(19) United States
(12) Patent Application Publication
(10) Pub. No.: US 2021/0257191 A1
(43) Pub. Date: Aug. 19, 2021

(54) PLASMA PROCESSING APPARATUS AND PLASMA PROCESSING METHOD

(71) Applicant: Kioxia Corporation, Tokyo (JP)

(72) Inventor: Yusuke KONDO, Yokkaichi Mie (JP)

(73) Assignee: Kioxia Corporation, Tokyo (JP)

(21) Appl. No.: 17/011,012

(22) Filed: Sep. 3, 2020

(30) Foreign Application Priority Data
Feb. 14, 2020 (JP) 2020-023752

(51) Int. Cl. H01J 37/32; H01L 21/67; H01L 21/683; H01L 21/3065

(52) U.S. Cl. CPC H01J 37/32724; H01L 21/67069; H01J 2237/3341; H01L 21/6833; H01L 21/3065; H01L 21/67103

(57) ABSTRACT

According to one embodiment, a plasma processing apparatus includes a chamber configured to be depressurized; a holder configured to hold a substrate in the chamber; an electrode, provided on the holder, that is configured to generate a plasma above the holder; and a liquid supply configured to supply a non-volatile liquid to a surface of the holder.

### CROSS-REFERENCE TO RELATED APPLICATION(S)

This application is based upon and claims the benefit of priority from. Japanese Patent Application No. 2020-023752, filed Feb. 14, 2020, the entire contents of which are incorporated herein by reference.

### FIELD

Embodiments described herein relate generally to a plasma processing apparatus and a plasma processing method.

### BACKGROUND

A plasma processing apparatus, such as a plasma etching apparatus or a plasma CVD (Chemical Vapor Deposition) apparatus, controls the temperature of a substrate held by a substrate holder by controlling the temperature of the substrate holder during plasma processing of the substrate. The substrate holder attracts and holds the substrate, e.g., with an electrostatic chuck (ESC). Helium gas is generally present between a surface of the substrate holder and a back surface of the substrate.

As the thermal load of plasma processing increases, it is becoming difficult to conduct heat uniformly from the substrate to the substrate holder during plasma processing. This may produce an in-plane variation in the temperature of the substrate, thereby creating a temperature distribution.

### DESCRIPTION OF THE DRAWINGS

FIG. 1A is a plan view showing a configuration of a plasm dry etching apparatus according to a first embodiment.

FIG. 1B is a plan view showing another configuration of the plasm dry etching apparatus.

FIG. 2 is a schematic cross-sectional view showing a configuration of a plasma reaction section.

FIG. 3 is a plan view showing a configuration of a substrate holder, etc.

FIG. 4A shows chemical formulae for ionic liquids.

FIG. 4B shows a chemical formula for ionic liquid.

FIG. 5 is a flow diagram of an etching process according to the first embodiment.

FIG. 6 is a cross-sectional view showing a configuration of a substrate holder and its vicinity of an etching apparatus according to a second embodiment.

FIG. 7 is a plan view showing a configuration of a substrate holder, etc. according to a variation of the second embodiment.

FIG. 8 is a schematic cross-sectional view showing a configuration of a substrate holder and its vicinity according to a third embodiment.

### DETAILED DESCRIPTION

Embodiments provide a plasma processing apparatus and a plasma processing method which can improve the in-plane uniformity of the temperature of a substrate during plasma processing.

In general, according to one embodiment, a plasma processing apparatus includes a chamber configured to be depressurized; a holder configured to hold a substrate in the chamber; an electrode, provided on the holder, that is configured to generate a plasma above the holder; and a liquid supply configured to supply a non-volatile liquid to a surface of the holder.

Embodiments of the present disclosure will now be described with reference to the drawings. The embodiments do not limit the present disclosure. The drawings are schematic or conceptual; thus, the size ratio between components or elements, etc. are not necessarily to scale. In the drawings and in the following description, the same symbols are used for the same or similar components or elements, and a detailed description thereof will sometimes be omitted.

### First Embodiment

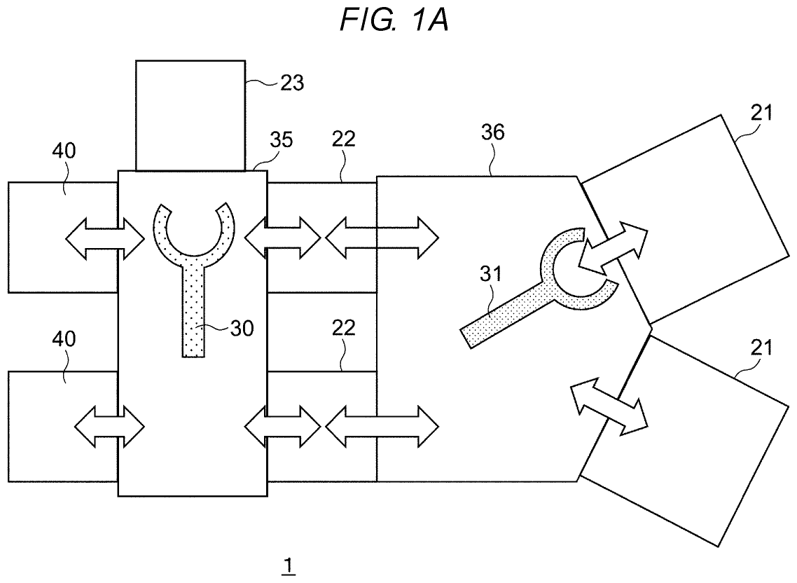

FIG. 1A is a plan view showing a configuration of a plasm dry etching apparatus (hereinafter also referred to as the etching apparatus) 1 according to a first embodiment. The etching apparatus 1 of this embodiment is an etching apparatus for performing, for example, an Reactive Ion Etching (RIE) method, and includes a plasma reaction section(s) (reactor) 21, a blowing section(s) (blower) 22 and an asking chamber(s) 23. There is no particular limitation on the number of chambers, such as the plasma reaction section(s) 21, the blowing section(s) 22 and the ashing chamber(s) 23, which are connected to wafer conveyance sections 35, 36; any desired number of such chambers may be provided.

Besides a plasm dry etching apparatus, other type of plasma processing apparatus such as a plasma Chemical Vapor Deposition (CVD) apparatus may be used in this embodiment.

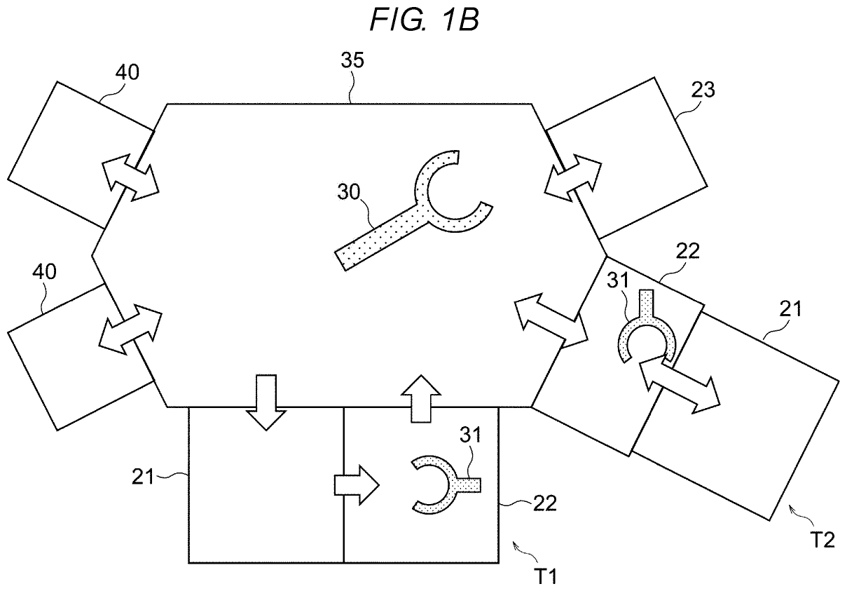

The plasma reaction section 21 houses a semiconductor wafer W, and performs plasma etching of the semiconductor wafer W. More details of the configuration of the plasma reaction section 21 will be described later with reference to FIG. 2.

After processing the semiconductor wafer W in the plasma reaction section 21, the blowing section 22 blows a gas, such as nitrogen gas, onto aback surface of the semiconductor wafer W to blow off an ionic liquid adhering to the back surface of the semiconductor wafer W, thereby drying the back surface of the semiconductor wafer W.

The ashing chamber 23 performs ashing of the semiconductor wafer W e.g. with oxygen to remove a mask formed on the semiconductor wafer W or a deposit formed by plasma processing.

The wafer conveyance sections (conveyors) 35, 36 have built-in robot arms 30, 31, respectively, and can convey the semiconductor wafer W from a load lock chamber 40 to the plasma reaction section 21 or the blowing section 22, or convey the semiconductor wafer W from the plasma reaction section 21 or the blowing section 22 to the load lock chamber 40. The plasma reaction section 21, the blowing section 22, the load lock chamber 40 and the wafer conveyance section 35 have been vacuumed and depressurized. The interior of the wafer conveyance section 36 may be in a vacuumed and depressurized state, or may be in a nitrogen (N₂) purge atmosphere.

The back surface of the semiconductor wafer W is sometimes wet with an ionic liquid during conveyance of the semiconductor wafer W from the plasma reaction section 21 to the blowing section 22. The robot arm 31 conveys the semiconductor wafer W with an ionic liquid attached thereto. On the other hand, the robot arm 30 conveys the semiconductor wafer W without an ionic liquid attached thereto.

The interior of each of the wafer conveyance sections 35, 36, the blowing section 22 and the plasma reaction section 21 is in a depressurized state or in a nitrogen (N₂) purge atmosphere during conveyance of the semiconductor wafer W. However, the interior of the plasma reaction section 21 is temporarily brought to atmospheric pressure when introducing or discharging the below-described ionic liquid IL into or from the plasma reaction section 21. For example, after supplying the ionic liquid IL at atmospheric pressure, the interior of the plasma reaction section 21 is brought to a depressurized state when performing plasma processing. The interior of the plasma reaction section 21 is again brought to atmospheric pressure when discharging the ionic liquid IL after the plasma processing.

FIG. 1B is a plan view showing another configuration of the etching apparatus 1. The plasma reaction section(s) 21, the blowing section(s) 22, the asking chamber(s) 23 and the load lock chamber(s) 40 are disposed in a cluster around the wafer conveyance section 35. In the embodiment of FIG. 1B, the etching apparatus 1 is not provided with the wafer conveyance section 36, and the robot arm 31 is disposed in each blowing section 22. Thus, the blowing section 22 also has the function of the wafer conveyance section 36.

In a conveyance system T1, a semiconductor wafer W is conveyed by the robot arm 30 to the plasma reaction section 21. After processing of the semiconductor wafer W, the semiconductor wafer W is conveyed by the robot arm 31 to the blowing section 22 and, after blowing, the semiconductor wafer W is conveyed from the blowing section 22 by the robot arm 30 and/or the robot arm 31.

In a conveyance system T2, a semiconductor wafer W is conveyed by the robot arm 30 to the blowing section 22, and conveyed by the robot arm 31 to the plasma reaction section 21. After processing of the semiconductor wafer W, the semiconductor wafer W is conveyed by the robot arm 31 to the blowing section 22 and, after blowing, the semiconductor wafer W is conveyed from the blowing section 22 by the robot arm 30 and/or the robot arm 31.

Also in the etching apparatus 1 of FIG. 1B, the interior of each of the wafer conveyance section 35, the blowing section 22 and the plasma reaction section 21 is in a depressurized state or in a nitrogen (N₂) purge atmosphere during conveyance of the semiconductor wafer W. The interior of the plasma reaction section 21 is temporarily brought to atmospheric pressure when introducing or discharging the ionic liquid IL into or from the plasma reaction section 21.

FIG. 2 is a schematic cross-sectional view showing a configuration of the plasma reaction section 21. The plasma reaction section 21 includes a chamber 100, a shower head 110, a substrate holder 120, an edge ring 125, a plasma electrode 140, a cooling mechanism (e.g., one or more openings) 141, substrate chucks 150, a high-frequency power source 160, a matching circuit 161, a liquid container 170, a valve 175, a liquid pipe Pin, a liquid pipe Pout, a liquid waste container 180, a valve 185, an etching material container 190, a gas pipe Pg, a valve 195, a memory 198, and a controller 199.

The interior of the chamber 100 has been depressurized into a vacuum state.

The shower head 110 has a hollow structure, and has a large number of holes that open toward the substrate holder 120. An etching gas is supplied through the holes into the chamber 100. A discharge portion 101 is provided in the chamber 100 so that the used etching gas is discharged through the discharge portion 101 to the outside of the chamber 100.

The semiconductor wafer W can be placed and held on the surface of the substrate holder 120. A substrate support portion 130 is provided on the surface of the substrate holder 120. The substrate support portion 130 supports the semiconductor wafer W from its back surface. An insulating material such as a ceramic material, for example, may be used for the substrate holder 120 and the substrate support portion 130. The substrate support portion 130 is a projecting portion formed continuously in a generally circular shape along the circumference of the semiconductor wafer W. Therefore, the ionic liquid IL can be collected on a surface region F1 of the substrate holder 120, surrounded by the substrate support portion 130.

The edge ring 125 is an annular member provided around the substrate holder 120 and formed integrally with the substrate holder 120. The edge ring 125 prevents displacement of the semiconductor wafer W.

The plurality of the substrate chucks 150 are provided on the edge ring 125. The substrate chucks 150 mechanically press on the periphery of the semiconductor wafer W from above toward the surface of the substrate holder 120, thereby fixing the semiconductor wafer W on the substrate holder 120. The substrate chucks 150 are thus so-called mechanical chucks. The substrate chucks 150 maybe provided such that they surround the circumference of the semiconductor wafer W, or they partially fix several portions of the semiconductor wafer W.

In this embodiment, the ionic liquid IL is electrically conductive, and therefore it is not possible to use an electromagnetic chuck.

The plasma electrode 140 is provided in the interior or at the bottom of the substrate holder 120 in order to generate a plasma in the chamber 100. The high-frequency power source 160 is connected to the plasma electrode 140 so that a high-frequency voltage is applied to the plasma electrode 140. On the other hand, the shower head 110 is grounded. An etching gas becomes a plasma state by the application of a high-frequency voltage between the plasma electrode 140 and the shower head 110. The plasma electrode 140 and the shower head 110 thus generate a plasma above the substrate holder 120. The cooling mechanism 141, which can pass a coolant therethrough, is provided within the plasma electrode 140. The cooling mechanism 141 cools the plasma electrode 140 and control its temperature during plasma processing. The cooling mechanism 141 can also control the temperature of the semiconductor wafer W via the substrate holder 120 and the ionic liquid IL.

The matching circuit 161 is provided between the plasma electrode 140 and the high-frequency power source 160. The matching circuit 161 matches the impedance of the high-frequency power source 160 with the impedance of the plasma, thereby preventing reflection of electric power.

The liquid container 170 houses the non-volatile ionic liquid IL. The liquid pipe Pin connects the liquid container 170 and the surface region F1 of the substrate holder 120 so that the ionic liquid IL can be supplied to the surface region F1 of the substrate holder 120. The liquid pipe Pin is provided with the valve 175 so that the liquid pipe Pin can be opened/closed to start/stop the flow of the ionic liquid IL from the liquid container 170 to the substrate holder 120.

The liquid waste container 180 houses the used ionic liquid IL. The liquid pipe Pout connects the liquid waste container 180 and the surface region F1 of the substrate holder 120 so that the ionic liquid IL can be discharged from the surface region F1 of the substrate holder 120. The liquid pipe Pout is provided with the valve 185 so that the liquid pipe Pout can be opened/closed to start/stop the flow of the ionic liquid IL from the substrate holder 120 to the liquid waste container 180.

The liquid container 170 supplies the ionic liquid IL to the surface region F1, while the liquid waste container 180 recovers the ionic liquid IL from the surface region F1. During etching, the valves 175, 185 are closed so that the ionic liquid IL will not leak out of the liquid pipes due to the pressure in the chamber 100.

The etching material container 190 houses an etching material as a source of an etching gas. The gas pipe Pg connects the etching material container 190 and the shower head 110 so that the etching gas can be supplied to the shower head 110. The gas pipe Pg is provided with the valve 195 so that the gas pipe Pg can be opened/closed to start/stop the flow of the etching gas from the etching material container 190 to the shower head 110.

The controller 199 controls the liquid container 170 and/or the valve 175, the liquid waste container 180 and/or the valve 185, and the etching material container 190 and/or the valve 195. The memory 198 stores, for example, a program for controlling the etching apparatus 1. The memory 198 also stores information on the supply amount, the discharge amount and the timing of supply/discharge of the ionic liquid IL, and on the supply amount and the timing of supply of the etching gas. The memory 198 may be either embedded in or external to the controller 199.

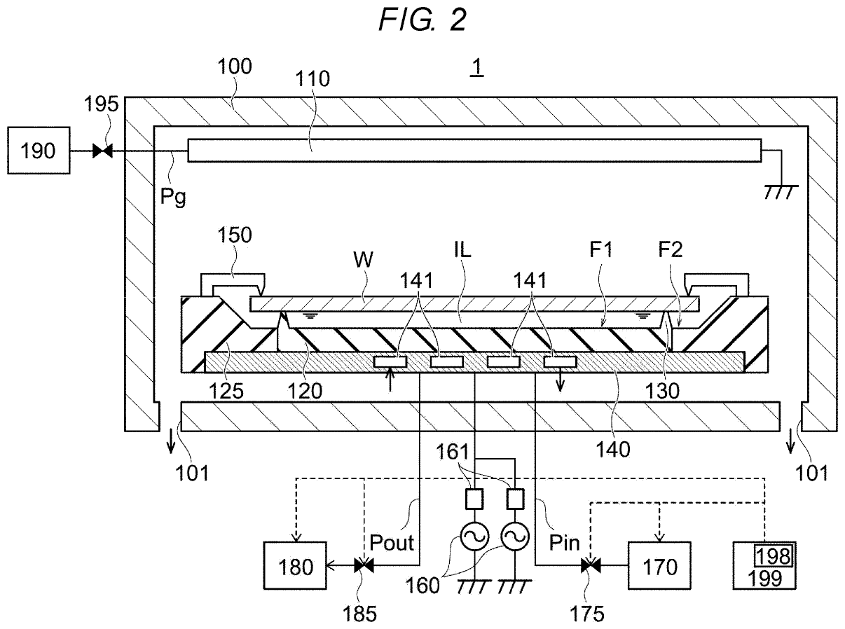

FIG. 3 is a plan view showing a configuration of the substrate holder 120, etc. A substrate support portion 130 is provided on the surface of the substrate holder 120. The substrate support portion 130 is formed continuously in a generally circular shape along the circumference of the substrate holder 120. The surface of the substrate holder 120, surrounded by the substrate support portion 130, is the surface region F1. The surface of the substrate holder 120 is approximately horizontal, and the ionic liquid IL can be collected on the surface region F1 of the substrate holder 120. The ionic liquid IL is collected to a position close to the top of the substrate support portion 130 so that when the semiconductor wafer W is held on the substrate holder 120, the ionic liquid IL contacts the entire area, corresponding to the surface region F1, of the back surface of the semiconductor wafer W. Therefore, heat from the semiconductor wafer W is transferred to the substrate holder 120 via the ionic liquid IL.

The amount of the ionic liquid IL that can be collected on the surface region F1 of the substrate holder 120 is determined by the area of the surface region F1 and the height of the substrate support portion 130. The surface of the ionic liquid IL may be slightly lower than the top of the substrate support portion 130 as long as the space between the back surface of the semiconductor wafer W and the surface region F1 of the substrate holder 120 can be filled with the ionic liquid IL or, due to the surface tension, maybe slightly higher than the top of the substrate support portion 130. While in this embodiment the ionic liquid IL fills the space between the surface region F1 of the substrate holder 120 and the semiconductor wafer W, the ionic liquid IL is not supplied to a surface region F2 of the substrate holder 120, located outside the surface region F1.

The memory 198 stores the volume of the space, surrounded by the surface region F1 of the substrate holder 120, the substrate support portion 130 and the semiconductor wafer W, as a supply amount of the ionic liquid IL. Based on the supply amount stored in the memory 198, the controller 199 controls the liquid container 170 or the valve 175 to supply the ionic liquid IL in approximately the same amount as the above volume to the surface region F1 of the substrate holder 120.

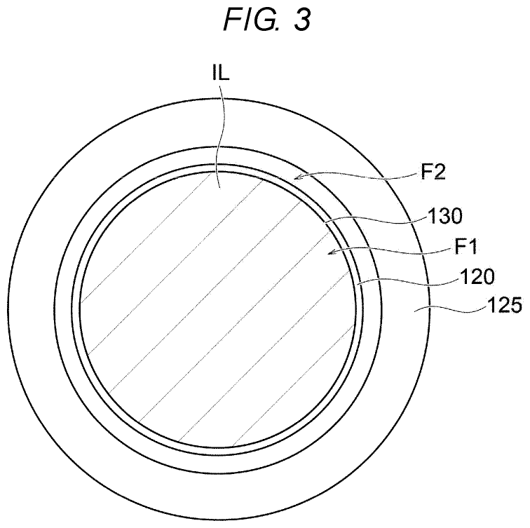

FIG. 4A shows chemical formulae for examples of the ionic liquid IL. The ionic liquid IL is a salt which is liquid at room temperature and composed of an ion. The ionic liquid IL is non-volatile, and its vapor pressure is approximately zero (0.001 Pa to 0.1 Pa) . The relative permittivity of the ionic liquid IL is 11 to 12. While the ionic liquid IL has a high electrical conductivity, it has a high heat capacity, and therefore it is stable thermally and chemically. The melting point of the ionic liquid IL is not more than 20° C. Examples of the ionic liquid IL may include the organonitrogen materials shown in FIG. 4A, namely an ammonium salt, an imidazolium salt, a pyridinium salt, a sulfonium salt, and a phosphonium salt. R1 to R4 each represent, for example, an alkyl group (CH₃, CH₂CH₃, (CH₂)ₓCH₃, CH₂CH₂OCH₃, etc.). In particular, when the ionic liquid IL is an ammonium salt, each of R1 to R3 may be, for example, CH₂CH₃, and R4 may be, for example, (CH₂)₄CH₃. When the ionic liquid IL is an imidazolium salt, R1 may be, for example, CH₃, and R2 may be, for example, (CH₂)₃CH₃. Examples of the X⁻of FIG. 4A may include Cl⁻, Br⁻, I⁻, BF₄⁻, PF₆⁻, and (CF₃SO₂) ₂N⁻.

An etching process using the etching apparatus 1 according to this embodiment will now be described.

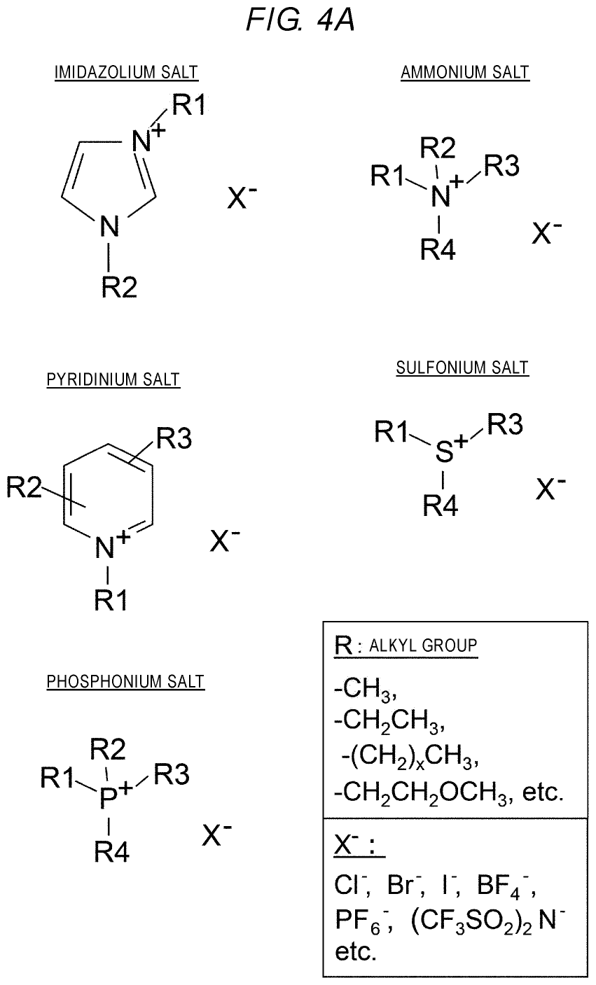

FIG. 5 is a flow diagram of an etching process according to the first embodiment.

First, the robot arm 30 conveys a semiconductor wafer W from the load lock chamber 40 to the chamber 100 of the plasma reaction section 21 (S20) The semiconductor wafer W is placed on the substrate support portion 130 of the substrate holder 120, and fixed on the substrate holder 120 by the substrate chucks 150.

Next, the ionic liquid IL is supplied from the liquid container 170 to the surface region F1 of the substrate holder 120 (S30). The controller 199 controls the liquid container 170 or the valve 175 so that the ionic liquid IL, in the supply amount stored in the memory 198, will be supplied to the substrate holder 120. Thus, the valve 175 opens, and the ionic liquid IL is supplied onto the surface region F1 of the substrate holder 120 until it reaches the vicinity of the top of the substrate support portion 130. In order to prevent the ionic liquid IL from squirting (leaking) out of the opening of the liquid pipe Pin, the controller 199 raises the pressure in the chamber 110 close to atmospheric pressure upon the supply of the ionic liquid IL. Thereafter, the valve 175 is closed, and then the interior of the chamber 100 is depressurized again. This prevents the ionic liquid IL from squirting out of the liquid pipe Pin.

The space between the surface region F1 of the substrate holder 120 and the back surface of the semiconductor wafer W thus becomes filled with the ionic liquid IL (S30) . The back-surface region, facing the surface region F1 of the substrate holder 120, of the back surface of the semiconductor wafer W entirely contacts the ionic liquid IL.

Next, plasma etching is performed (S40) . The controller 199 controls the etching material container 190 or the valve 195 to supply the etching gas to the shower head 110. The etching gas is supplied through the shower head 110 into the chamber 100. The high-frequency power source 160 is actuated to apply a high-frequency voltage between the plasma electrode 140 and the shower head 110, which brings the etching gas into a plasma state and effecting etching of the semiconductor wafer W.

While the semiconductor wafer W is heated on plasma etching, the heat is absorbed by the ionic liquid IL having a high heat capacity. The ionic liquid IL fills the space between the surface region F1 of the substrate holder 120 and the back surface of the semiconductor wafer W. Therefore, the temperature of the ionic liquid IL and the temperature of the semiconductor wafer W can be controlled (cooled) to fall within a predetermined range. This improves the in-plane uniformity of the temperature of the semiconductor wafer W.

After the completion of etching, in the chamber 100 of the plasma reaction section 21, the controller 199 opens the valve 185 to recover or otherwise collect the ionic liquid IL on the substrate holder 120. The ionic liquid IL is recovered from the surface region F1 of the substrate holder 120 into the liquid waste container 180 (S45). Also when recovering the ionic liquid IL, the controller 199 raises the pressure in the chamber 110 close to atmospheric pressure in order to prevent the ionic liquid IL from squirting out of the opening of the liquid pipe Pout.

Next, the robot arm 31 conveys the semiconductor wafer W from the plasma reaction section 21 to the blowing section 22 (S50) . In the blowing section 22, a dry gas, such as nitrogen gas, is blown onto the back surface of the semiconductor wafer W to blow off the ionic liquid IL adhering to the back surface of the semiconductor wafer W (S60).

Next, the robot arm 30 conveys the semiconductor wafer W from the blowing section 22 to the load lock chamber 40 (S80). The semiconductor wafer W is placed in a cassette, whereby the plasma etching for the semiconductor wafer W is completed.

A gas such as helium gas has a lower heat capacity than the ionic liquid IL. Therefore, if such a gas is used instead of the ionic liquid IL to cool the semiconductor wafer W, then a variation in the surface temperature of the semiconductor wafer W will be relatively large, i.e. the in-plane uniformity of the temperature of the semiconductor wafer W will be relatively poor. In that case, it is difficult to control the etching process, leading to a variation in shape or properties among semiconductor devices in the surface of the semiconductor wafer W.

In contrast, the etching apparatus 1 according to this embodiment can supply the ionic liquid IL, having a high heat capacity, between the substrate holder 120 and the semiconductor wafer W, and can recover the ionic liquid IL, as described above. This makes it possible to easily control the temperature of the semiconductor wafer W within a predetermined range, and to enhance the in-plane uniformity of the temperature.

### Second Embodiment

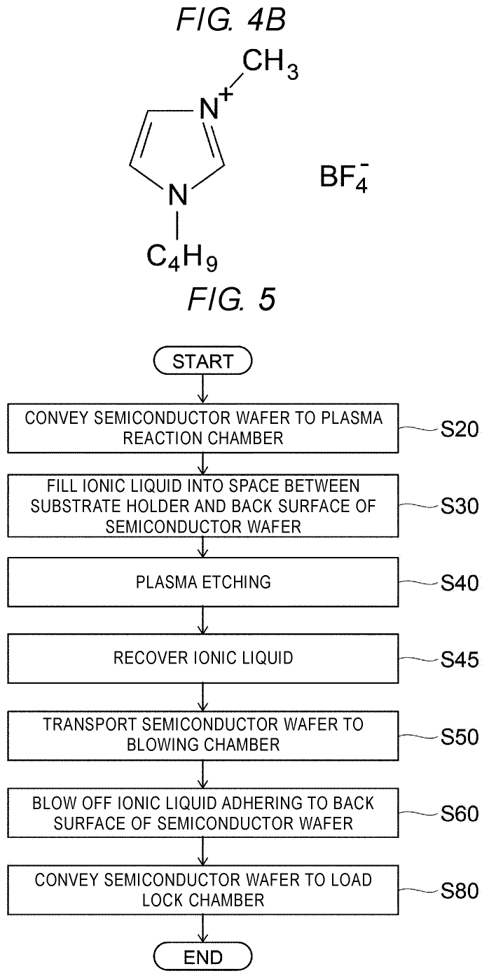

FIG. 6 is a cross-sectional view showing a configuration of a substrate holder and its vicinity of an etching apparatus according to a second embodiment.

An edge ring 125 is an annular member provided around the substrate holder 120 and formed integrally with the substrate holder 120. The edge ring 125 of the second embodiment has a portion projecting toward the peripheral surface of the semiconductor wafer W, and has a wafer-facing surface 126 that faces the peripheral surface of the semiconductor wafer W. The wafer-facing surface 126 extends approximately annularly along the peripheral surface of the semiconductor wafer W. A narrow gap G is formed between the wafer-facing surface 126 and the peripheral surface of the semiconductor wafer W.

The ionic liquid IL is not only supplied into the space between the surface region F1 of the substrate holder 120 and the back surface of the semiconductor wafer W, but supplied into the space between the surface region F2 of the substrate holder 120, located outside the surface region F1, and the back surface of the semiconductor wafer W until it fills the gap G. Accordingly, the ionic liquid IL contacts the entire back surface and the peripheral surface of the semiconductor wafer W. In this case, the amount of the ionic liquid IL to be supplied to the surface region F1 of the substrate holder 120 is equal to the volume of the space surrounded by the substrate holder 120, the edge ring 125 and the semiconductor wafer W. The memory 198 pre-stores the volume as a supply amount of the ionic liquid IL.

The remaining configuration of the second embodiment may be the same as the corresponding configuration of the first embodiment. The second embodiment can therefore achieve the same effect as the first embodiment.

Furthermore, according to the second embodiment, the ionic liquid IL contacts the entire back surface and the peripheral surface of the semiconductor wafer W. This makes it easier to control the temperature of the entire semiconductor wafer W, ranging from the center to the edge, and further enhances the in-plane uniformity of the temperature.

Though the gap G is very narrow, the surface of the ionic liquid IL in the gap G is exposed in the interior of the chamber 100. A difference in the relative permittivity between the ionic liquid IL and the semiconductor wafer W will bend the ion sheath of the plasma. In order to prevent such bending of the ion sheath of the plasma, the relative permittivity of the ionic liquid IL is preferably equal to that of the semiconductor wafer W. For example, when the semiconductor wafer W is made of silicon, the relative permittivity of the ionic liquid IL is preferably about 11.0 to 13.0 which is comparable to the relative permittivity of silicon (11.9 to 12.0). 1-butyl-3-methylimidazolium tetrafluoroborate shown in FIG. 4B, for example, may be used as the ionic liquid IL. FIG. 4B shows the chemical formula of 1-butyl-3-methylimidazolium tetrafluoroborate. The relative permittivity of 1-butyl-3-methylimidazolium tetrafluoroborate is 12.8. The use of such an ionic liquid IL can prevent bending of the ion sheath of the plasma, and can further enhance the in-plane uniformity of the temperature of the semiconductor wafer W.

(Variation)

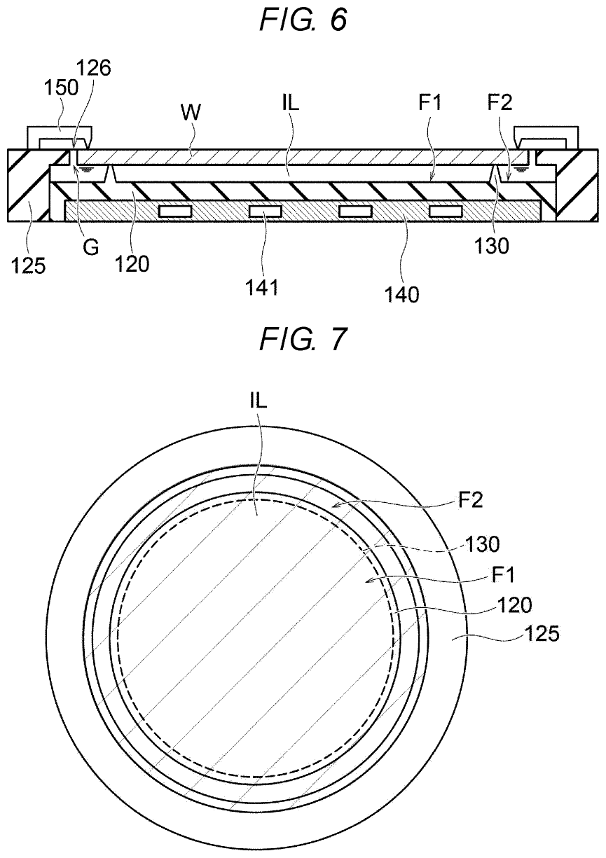

FIG. 7 is a plan view showing a configuration of a substrate holder 120, etc. according to a variation of the second embodiment. In this variation, a substrate support portion 130 is formed discontinuously in a generally circular shape along the circumference of the substrate holder 120. In the second embodiment, the ionic liquid IL is supplied not only to the surface region F1 of the substrate holder 120 but also to the surface region F2 located outside the surface region F1. Therefore, the substrate support portion 130 need not necessarily have a continuous shape, and may be formed in a discontinuous shape on the substrate holder 120. The remaining configuration of this variation may be the same as the corresponding configuration of the second embodiment. This variation can therefore achieve the same effect as the second embodiment.

### Third Embodiment

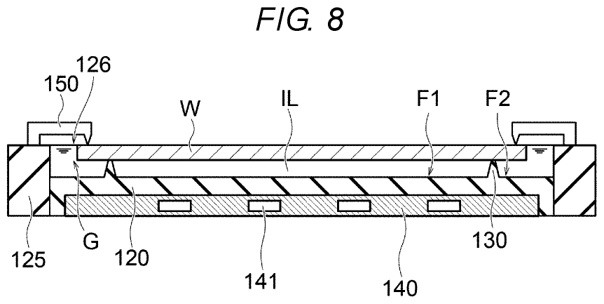

FIG. 8 is a schematic cross-sectional view showing a configuration of a substrate holder and its vicinity according to a third embodiment. An edge ring 125 according to the third embodiment does not have a portion projecting toward the peripheral surface of the semiconductor wafer W. Therefore, the gap G between the inner peripheral surface (wafer-facing surface) 126 of the edge ring 125 and the peripheral surface of the semiconductor wafer W is wide; the relatively wide surface of the ionic liquid IL is to be exposed in the chamber 100. Nevertheless, because of the very low vapor pressure of the ionic liquid IL, it little vaporizes even in a reduced-pressure atmosphere in the chamber 100.

The ionic liquid IL fills the space between the surface regions F1, F2 of the substrate holder 120 and the back surface of the semiconductor wafer W, and also fill the space between the peripheral surface of the semiconductor wafer W and the inner peripheral surface 126 of the edge ring 125. Thus, the ionic liquid IL contacts the entire back surface and the peripheral surface of the semiconductor wafer W. This makes it possible to easily control the temperature of the entire semiconductor wafer W, ranging from the center to the edge, and to further enhance the in-plane uniformity of the temperature.

In the third embodiment, the ionic liquid IL is exposed around the semiconductor wafer W, and the surface of the ionic liquid IL is made approximately flush with the front surface of the semiconductor wafer W. Thus, the ionic liquid IL is used as a substitute for an edge ring. Further, the relative permittivity of the ionic liquid IL may be made approximately equal to the relative permittivity of the semiconductor wafer W. This prevents bending of the ion sheath of the plasma, and further enhances the in-plane uniformity of the temperature of the semiconductor wafer W.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing apparatus comprising:
a chamber configured to be depressurized;
a holder configured to hold a substrate in the chamber;
an electrode, provided on the holder, that is configured to generate a plasma above the holder; and
a liquid supply configured to supply a non-volatile liquid to a surface of the holder.

2. The plasma processing apparatus according to claim 1, further comprising a chuck member, provided in the holder, that is configured to press on a peripheral portion of the substrate toward the surface of the holder.

3. The plasma processing apparatus according to claim 1, wherein the holder further comprises a projecting portion formed along a circumference of the substrate, wherein the liquid supply supplies the liquid to a first region of the surface of the holder that is surrounded by the projecting portion.

4. The plasma processing apparatus according to claim 3, further comprising a memory configured to store a volume of a space surrounded by the first region, the projecting portion and the substrate, wherein the liquid supply supplies the liquid in an amount approximately the same as the volume divided by an area of the first surface region.

5. The plasma processing apparatus according to claim 1, further comprising an annular member having a surface that faces a peripheral portion of a surface of the substrate.

6. The plasma processing apparatus according to claim 5, further comprising a projecting portion provided on the holder and formed discontinuously along a circumference of the substrate.

7. The plasma processing apparatus according to claim 1, wherein the liquid includes an ionic liquid.

8. A plasma processing method, comprising:
placing and holding a substrate on a holder;
filling a liquid into a space between a portion of a surface of the holder and a back surface of the substrate; and
performing plasma processing on the substrate.

9. The plasma processing apparatus according to claim 1, wherein the liquid has a melting point equal to or less than 20° C.

10. The plasma processing apparatus according to claim 1, wherein the liquid includes organonitrogen materials.

11. The plasma processing apparatus according to claim 1, wherein the electrode further comprises one or more openings.

12. The plasma processing apparatus according to claim 11, wherein each of the openings is configured to provide a coolant to control a temperature of the substrate via at least the liquid.

13. The plasma processing method according to claim 8, further comprising:
determining an amount of the liquid based on a volume of the space and an area of the portion of the surface of the holder.

14. The plasma processing method according to claim 8, wherein the liquid has a melting point equal to or less than 20° C.

15. The plasma processing method according to claim 8, wherein the liquid includes organonitrogen materials.

16. The plasma processing method according to claim 8, wherein the plasma processing includes Reactive Ion Etching.
